(19) United States
(12) Patent Application Publication
(10) Pub. No.: US 2010/0317278 A1
(43) Pub. Date: Dec. 16, 2010

(54) Cooling System for a Computer Server Cabinet in a Data Center

(75) Inventor: Barry Novick, Mamaroneck, NY (US)

Correspondence Address: EDWARDS ANGELL PALMER & DODGE LLP, P.O. BOX 55874, BOSTON, MA, 02205, US

(73) Assignee: BlackRock, Inc.

(21) Appl. No.: 12/797,702

(22) Filed: Jun. 10, 2010

Related U.S. Application Data
(60) Provisional application No. 61/185,861, filed on Jun. 10, 2009.

(51) Int. Cl. H05K 5/02; F24F 13/10; F25D 9/00

(52) U.S. Cl. 454/184; 454/290; 62/401

(57) ABSTRACT

A system for cooling computer equipment in a data center. The system includes a raised floor defining a pressurized under-floor plenum; a computer room air conditioning unit disposed on the raised floor and having a hot air inlet and a cold air outlet, wherein the cold air outlet is in fluid communication with pressurized under-floor plenum; and a server cabinet housing server equipment and including a pressurized vertical plenum in fluid communication with under-floor plenum via an inlet duct. The server cabinet is configured to receive a cold air stream from the under-floor plenum via the inlet duct into the vertical plenum and draw the cold air across the server equipment to provide cooling without the use of external fans. The system may also include an inflatable airfoil damper assembly disposed within the inlet duct and configured to provide failsafe variable airflow to the vertical plenum within the server cabinet.

### CROSS REFERENCE TO RELATED APPLICATION

This application claims priority to U.S. Provisional Patent Application No. 61/185,861, filed Jun. 10, 2009, the disclosure of which is incorporated herein by reference in its entirety.

### BACKGROUND OF THE INVENTION

1. Field of the Invention

The present invention is directed to environmental control of data centers. More specifically, the present invention involves systems and methods for directly and efficiently cooling information technology equipment housed within a cabinet in a data center.

2. Background of the Related Art

A typical data center consists of a climate-controlled room with rows of equipment racks housed within cabinets and arranged on a raised floor. Equipment housed within the cabinets may include servers and other electronic devices. Computer Room Air Conditioners (CRACs) collect hot air from the room and deliver cold, pressurized air to a plenum created below the raised floor. The raised floor typically includes a number of floor tiles, including perforated floor tiles that allow the pressurized air to flow up into the room.

Internal cooling mechanisms, such as fans, integrated within most computer equipment draws cold air from the front side of the equipment and exhausts hot air out the back side of the equipment. By organizing cabinets in alternating rows, with the fronts of the cabinets facing a “cold aisle” having perforated tiles and the backs of the cabinets facing a “hot aisle” with non-perforated tiles, the fans within the equipment pull the cold air coming up through the cold aisle across the equipment where heat transfer from the equipment to the air takes place. The air that has been heated is then exhausted to the hot aisle where it rises toward the ceiling of the data center room and is then drawn back through an inlet of the CRACs so that the process can be repeated.

The conventional data center setup described above has several inefficiencies. A significant amount of energy is wasted in moving excess volumes of air. Without containment, there is no mechanism to ensure that all of the cold air generated by the CRACs reaches the equipment racks where it can be used for cooling, nor is there a mechanism to prevent hot air from flowing into the equipment input. In addition, the conventional data center setup is a constant volume system, where the air delivery rate is not related to the heat load generated by the equipment housed within the cabinets. As a result, the amount of heat that can be transferred from the equipment housed within each cabinet is limited. The energy wasted in moving excess air, that is, air that does not serve to cool the equipment, can account for 10% or more of the total energy consumed in a data center.

Operators of data centers have dealt with this limitation by distributing equipment around the room to limit the maximum power density. By distributing equipment around the room, the heat load within the data center can be evened out.

Several high-density cooling techniques have been employed when higher power densities are required. One method involves mounting air conditioning units directly above each of the cabinets. This “extreme density” solution requires piping refrigerant gases to each of the air conditioning units. Although this method adequately provides the required cooling, it is costly and relies on the use of additional fans, which can add inefficiencies into the cooling system.

Another method involves mounting cooling equipment between equipment racks that uses either chilled water units or traditional air-cooled air conditioning units to inject cold air into the side of the adjacent equipment racks. This method is costly and takes up valuable rack space within the data center. Chilled water units require water piping to be installed under the floor, and the small fans have lower mechanical efficiency than the large CRAC units. Both types of local cooling solutions require an expensive and intrusive piping system to be installed within the data center.

Other methods for high power density cooling include using auxiliary fans to force air both into and out of the equipment cabinet, or using chilled water fan-coils directly in the equipment racks. Both methods rely on external fans which consume energy and are prone to failure. Chilled water fan-coils also require expensive piping and may expose the equipment to the risk of water contact. Further, these systems do not provide the redundancy of multiple cooling air sources.

Some data centers have addressed the cooling problem by creating either hot isle or cold isle containment systems. These systems allow for efficient cooling at the expense of a loss of flexibility. Every rack in the data center must be architecturally part of one of the containment isles in order to work. As a result, these systems are generally only applicable to new builds.

Each of the methods mentioned above are expensive to purchase, install, and operate. These methods introduce complexity and additional points of failure to the critical cooling systems within a data center. Consequently, there is a need in the art for a data center cooling system that is simple, fail-safe, and more efficient than prior-art methods.

### SUMMARY OF THE INVENTION

Advantages of the present invention will be set forth in and become apparent from the description that follows. Additional advantages of the invention will be realized and attained by the methods and systems particularly pointed out in the written description and claims, as well as from the appended drawings.

To achieve these and other advantages and in accordance with the purpose of the invention, as embodied herein, the invention includes a system for cooling computer equipment in a data center. The system includes a raised floor defining a pressurized under-floor plenum; a computer room air conditioning unit disposed on the raised floor and having a hot air inlet and a cold air outlet, wherein the cold air outlet is in fluid communication with pressurized under-floor plenum; and a server cabinet housing server equipment and including a pressurized vertical plenum in fluid communication with under-floor plenum via an inlet duct. The server cabinet is configured to receive a cold air stream from the under-floor plenum via the inlet duct into the vertical plenum and draw the cold air across the server equipment to provide cooling without the use of external fans. The system may also include an inflatable airfoil damper assembly disposed within the inlet duct and configured to provide failsafe variable airflow to the vertical plenum within the server cabinet.

A system for cooling electronic equipment in a data center is also disclosed. The system includes a raised floor defining an under-floor plenum; an air conditioner having a hot-air inlet and a cold-air outlet, with the cold-air outlet in fluid communication with the under-floor plenum; and a cabinet housing electronic equipment and including an airtight, pressurized vertical plenum in fluid communication with the under-floor plenum via an inlet duct. The cabinet is configured to receive a cold air flow from the under-floor plenum via the inlet duct into the vertical plenum and to draw the cold air across the electronic equipment to cool the electronic equipment. The system may also include an inflatable airfoil damper assembly disposed within the inlet duct and configured to provide failsafe variable airflow to the vertical plenum within the cabinet.

A method for cooling electronic equipment in a data center is also provided. the method includes the steps of: providing an air conditioner having a cold air outlet in fluid communication with an under-floor plenum; providing a cabinet housing electronic equipment and including an airtight, pressurized vertical plenum in fluid communication with the under-floor plenum via an inlet duct; drawing cold air produced by the air conditioner from the under-floor plenum, through the inlet duct and into the vertical plenum; and drawing the cold air from the vertical plenum through the electronic equipment to cool the electronic equipment and to heat the air.

The method may also include the step of modulating the flow of cold air from the air conditioner using a variable air volume control to maintain a first set-point temperature within the under-floor plenum. The method may further include the step of varying the flow of cold air through the inlet duct using an inflatable airfoil damper. The method may also include the step of inflating a plurality of elongated airfoils that make up the inflatable airfoil damper, with each airfoil having a longitudinal axis that is substantially parallel to the direction of the air flow.

### BRIEF DESCRIPTION OF THE DRAWINGS

So that those skilled in the pertinent art will readily understand how to implement the systems and methods for efficient cooling of a server cabinet within a data center without undue experimentation, preferred embodiments of the systems and methods will be described in detail below with reference to the following figures:

FIG. 1 is a schematic illustration of the cooling system for server cabinets in a data center, according to the present invention;

FIG. 2 is a detailed schematic illustration of a server cabinet that forms a part of the cooling system shown in FIG. 1;

FIG. 3 is a detailed view of the server cabinet of FIG. 2, showing the deflated airfoils of the airfoil damper situated within an inlet duct connecting an under-floor plenum to a vertical pressurized plenum within the server cabinet;

FIG. 4 is a detailed view of the server cabinet of FIG. 2, showing the inflated airfoils situated within an inlet duct connecting an under-floor plenum to a vertical pressurized plenum within the server cabinet;

FIG. 5 is a perspective view of a computer server cabinet forming a part of the cooling system of the present invention;

FIG. 6 is a orthogonal front view of an exemplary embodiment of a server cabinet according to the present invention;

FIG. 7 is a orthogonal side view of an exemplary embodiment of a server cabinet according to the present invention, showing an inlet duct;

FIG. 8 is a orthogonal rear view of an exemplary embodiment of a server cabinet according to the present invention, showing a perforated door allowing hot air to flow from the cabinet; and

FIG. 9 is a orthogonal bottom view of an exemplary embodiment of a server cabinet according to the present invention, showing an inlet duct.

### DETAILED DESCRIPTION OF PREFERRED EMBODIMENTS

Reference will now be made in detail to the present preferred embodiments of the systems and methods for cooling computer equipment in a data center. In one exemplary embodiment, the system comprises a computer server cabinet housing a plurality of servers mounted within the cabinet on a plurality of racks. Although servers and server cabinets are referenced throughout this disclosure, it should be understood that the systems and methods of the present disclosure may be applied to the cooling of other types of equipment and in other types of applications.

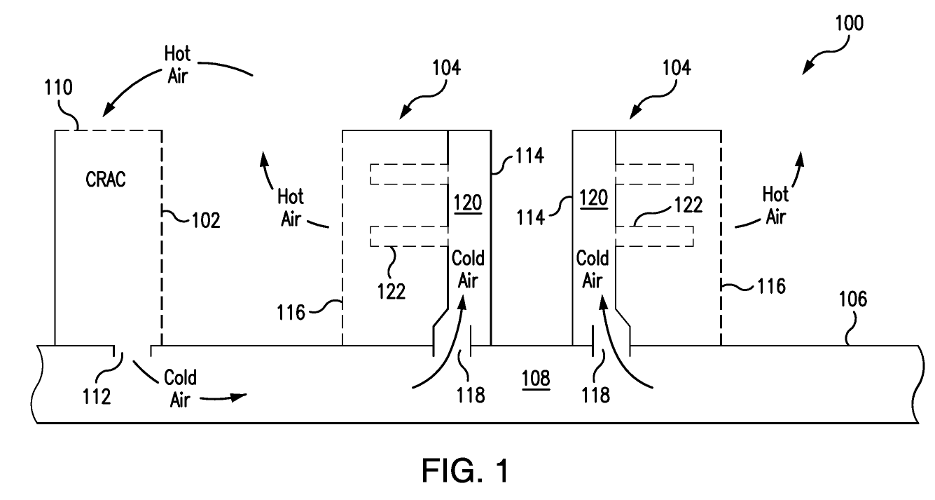

For purposes of explanation and illustration, and not limitation, an exemplary embodiment of a cooling system in accordance with the present invention is shown in FIG. 1 and designated generally by the reference numeral 100. Cooling system 100 includes at least one Computer Room Air Conditioner (CRAC) 102, and at least one server cabinet 104. CRAC 102 and server cabinet 104 are positioned on a raised floor 106 that defines an under-floor plenum 108. CRAC 102 includes a hot air inlet 110 at a predetermined height above raised floor 106 for intake of hot air. CRAC 102 also includes an cold air outlet 112 in fluid communication with the under-floor plenum 108. Cold, pressurized air exiting cold air outlet 112 of CRAC 102 is forced into under-floor plenum 108. In one exemplary embodiment, raised floor 106 provides a seal to prevent the cold air from leaking through the floor.

Server cabinet 104 includes a front portion 114 and a back portion 116, as well as an inlet duct 118 in fluid communication with under-floor plenum 108. Inlet duct 118 allows the cold, pressurized air within under-floor plenum 108 to flow upward into a vertical plenum 120 where it is drawn through server equipment 122 mounted within the rack space of server cabinet 104. The cold, pressurized air may be drawn through server equipment 122 by an internal cooling mechanism, such as a fan, housed within or mounted near server equipment 122. As the air travels through server 122, heat generated by the operation of electrical and mechanical components of server equipment 122 is transferred from the components of server 122 to the air. The heated air then flows out of the back portion 116 of server cabinet 104 and is again introduced into CRAC 102 through hot air inlet 110.

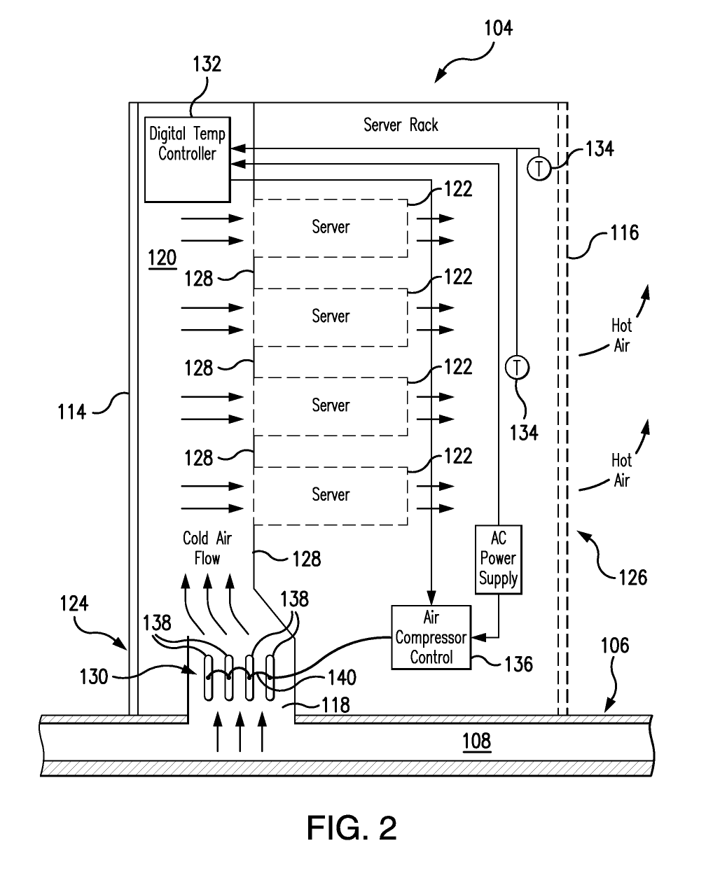

FIG. 2 illustrates a detailed schematic view of server cabinet 104. Server cabinet 104 includes one or more servers 122 or other equipment mounted on racks within the server cabinet. Inlet duct 118 forms an air-tight seal with raised floor 106 and is in fluid communication with both the under-floor plenum 108 and the vertical plenum 120. In the exemplary embodiment shown, front portion 114 of server cabinet 104 includes a air-tight front door 124, while back portion 116 includes a perforated back door 126. Rack space within server cabinet 104 that is not occupied by server equipment 122 is blanked off with plates 128 to form the pressurized vertical plenum 120 between front door 124 and a front surface of the server equipment 122. Plates 128 may be made of metal, plastic, a combination of these two materials, or any other suitable materials.

Pressurizing vertical plenum 120 naturally forces the cold air forced up through inlet duct 118 to follow the only available path—directly through server equipment 122. Cooling system 100 thus eliminates the inefficiencies and points of failure of previous cooling systems, because substantially all of the cold air generated by CRAC 102 is routed directly through server equipment 122 and is used to directly cool the server equipment. This eliminates the increased power requirement and decreased efficiency that results from using external fans and power sources. The only fan power utilized by cooling system 100 comes from the fans in CRAC 102 and the fans within server equipment 122.

In one exemplary embodiment, front door 124 of server cabinet 104 is made of glass, which allows for visual inspection of server equipment 122 while still providing the airtight seal needed to pressurize vertical plenum 120. In one exemplary embodiment, front door may be made of glass surrounded by a rubberized seal to maintain the pressure within vertical plenum 120.

In one exemplary embodiment, server equipment 122 within server cabinet 104 operates at a steady state of power consumption, and the volume of air admitted to the cabinet is set with an adjustable baffle positioned within inlet duct 118. The adjustable baffle may be made of metal or any other suitable material, and may be adjusted manually, or automatically by a digital controller.

In another exemplary embodiment, server equipment 122 may have a modulating load characteristic that requires a variable air flow from under-floor plenum 108 to vertical plenum 120. As shown in FIG. 2, an inflatable airfoil damper 130 may be positioned within inlet duct 118 of server cabinet 104 to regulate the flow of air from under-floor plenum 108 into vertical plenum 120. Only the amount of air required to cool server equipment 122 housed within server cabinet 104 will be admitted. The only path the air can take to exit server cabinet 104 is through server equipment 122.

Cooling system 100 may include a controller 132 and one or more temperature sensors 134 to regulate the temperature at the back portion 116 of server cabinet 104. For example, controller 132 may be programmed to maintain the temperature at the back portion 116 of server cabinet 104 at a predetermined set-point. In one exemplary embodiment, controller 132 comprises a microprocessor based thermostat. A plurality of temperature sensors 134 may be positioned in the back portion 116 of server cabinet 104 and interface with controller 132. If the temperature in server cabinet 104 drops below the set-point, an air compressor 136 in communication with controller 132 will slowly inflate one or more airfoils 138 that form a part of airfoil damper 130 to decrease the volume of air flowing from under-floor plenum 108 to vertical plenum 120. If temperature sensors 134 detect that the temperature in server cabinet 104 has risen above the set-point, a bleed solenoid will deflate airfoil dampers 130 to increase the flow of cold air and thus decrease the temperature within the cabinet. In one exemplary embodiment, CRAC 102 utilizes a variable air volume (VAV) control, which allows the fan speed of CRAC 102 to modulate as necessary to maintain a static-pressure set-point within under-floor plenum 108.

Traditional air flow dampers are not sufficiently reliable for use in a data center, where it is often critical to maintain the equipment up and running on a continuous basis at all hours of the day and night. Mechanical dampers, damper linkages, and actuators are prone to fail unexpectedly. Such a failure could result in a loss of air flow to the cabinet, causing the server equipment to overheat, leading catastrophic failure and data loss. For a corporation or other data center operator, this could mean millions of dollars in lost profits and potential liability to third parties.

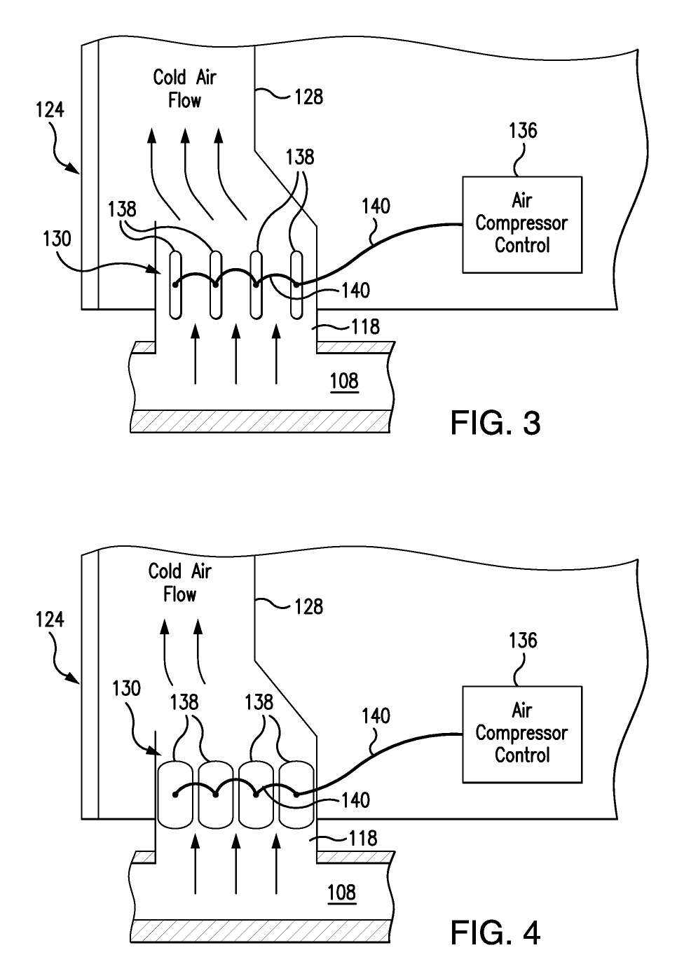

FIGS. 3 and 4 illustrate the operation of inflatable airfoil damper 130. Inflatable airfoil damper 130 allows cooling system 100 to provide variable air flow to server cabinet 104 based on the heat load produced by server equipment 122 without the risk of catastrophic failure associated with previous damper systems. As shown in FIGS. 3 and 4, inflatable airfoil damper 130 may comprise a plurality of elongated, parallel airfoils 138, each having a longitudinal axis that is oriented substantially parallel to the flow of cold air as the air moves from under-floor plenum 108 into vertical plenum 120. FIGS. 3 and 4 show only two of the possible states of airfoils 138. It is contemplated that in conjunction with controller 132 and air compressor 136, airfoils 138 could hold any suitable amount of air and thus accommodate a wide variety of airflow volume to vertical plenum 120.

Airfoils 138 may also be of any suitable shape and size that would permit variable airflow. In one exemplary embodiment airfoils 138 may include tapered ends that facilitate air flow. The angle of airfoils 138 may also be adjustable to further control the flow of cold air into vertical plenum 120. Although four airfoils 138 are shown in FIGS. 2-4, any suitable number of airfoils 138 may be used to form inflatable baffle 130. In one exemplary embodiment, airfoils 138 are made of aluminum.

FIG. 3 illustrates the airfoils 138 in a deflated state. Airfoils 138 may include internal air bladders in fluid communication with air compressor 136 via one or more pneumatic lines 140. When controller 132 determines that a decrease in cooling and thus a decrease in cool air flow is required, controller 132 interfaces with air compressor 136, which in turn inflates the airfoils 138 via pneumatic lines 140.

As shown in FIG. 4, as airfoils 138 inflate, the flow of air from under-floor plenum 108 to vertical plenum 120 is restricted. If controller 132 subsequently determines that greater air flow is needed, the controller interfaces with air compressor 136 to deflate airfoils 138 and increase the cold air flowing into vertical plenum 120.

Any malfunction within cooling system 100 will result in a loss of air pressure at air compressor 136 and pneumatic line 140, which will cause airfoils 138 of inflatable airfoil damper 130 to deflate, that is, revert to their original thin profile, which in turn allows the maximum air flow through server cabinet 104. Inflatable airfoil damper 130 provides for failsafe operation of cooling system 100; the default state of cooling system 100 will allow the maximum amount of cold air to flow upward through vertical plenum 120 and through the server equipment.

Advantageously, cooling system 100 allows for higher cabinet power densities than are possible with conventional data center cooling systems. Power density measures the power consumption used by equipment based on the foot print needed to power and cool the equipment. Using standard server cabinets and perforated floor tiles, maximum power density is limited to approximately five kilowatts per cabinet. With suitable under-floor static pressure, cooling system 100 allows for up to approximately 15 kilowatts per server cabinet. Cooling system 100 increases power density because there is no need for external fans or other equipment to efficiently cool the equipment housed within cabinet 104.

Additionally, in a data center using cooling system 100, high-density cabinets can be placed in any location within the data center. Because the amount of cooling air is a function only of the control device, there is no limitation as to equipment groupings, as was the case with prior-art designs. Cooling system 100 also obviates the need to orient the server cabinets in a specific way. Using cooling system 100, there is no need for hot aisles and cold aisles; in essence, the entire room functions as a hot isle, while under-floor plenum 108 functions as a cold aisle. Cooling system 100 therefore allows for placement of many more cabinets within a given data center space that is possible with conventional cooling systems.

Cooling system 100 also provides improvements in energy efficiency. The energy used by the fans within CRAC 102 is limited to the current air demands of the heat load produced within server cabinet 104 at any given moment. No energy is wasted circulating excess air not used for cooling. Because a higher temperature difference across CRAC 102 is possible using cooling system 100, CRAC 102 is able to operate in a much more efficient region of its performance envelope.

As described above, use of inflatable airfoil damper 130 provides simple and failsafe variable airflow to server cabinet 104. Any malfunction to the airflow control system will result in an increase in airflow rather than a decrease in airflow and a loss of cooling.

Cooling system 100 is also much more cost effective than previous high power density cooling systems. Cooling system 100 requires no special piping or wiring within the data center, and no local high speed fans are required. The lack of additional fans (other than those housed within CRAC 102 and server equipment 122) reduces noise while increasing efficiency and reliability, because fan operation requires a significant amount of energy and introduces another point of failure within a cooling system.

Because the entire data center room functions as the hot aisle, cooling system 100 is readily compatible with air-side economizers and emergency cooling via roof venting. Because the air is forced through server equipment 122, higher discharge set-points are possible. The higher set-points allow for a greatly extended economizer operation window. A conventional chilled water system requires chilled water at 42° F. to achieve discharge air at 55° F. However, with a 70° F. discharge set-point, 57° chilled water can be utilized. This has the potential to increase available free cooling hours by nearly 50%.

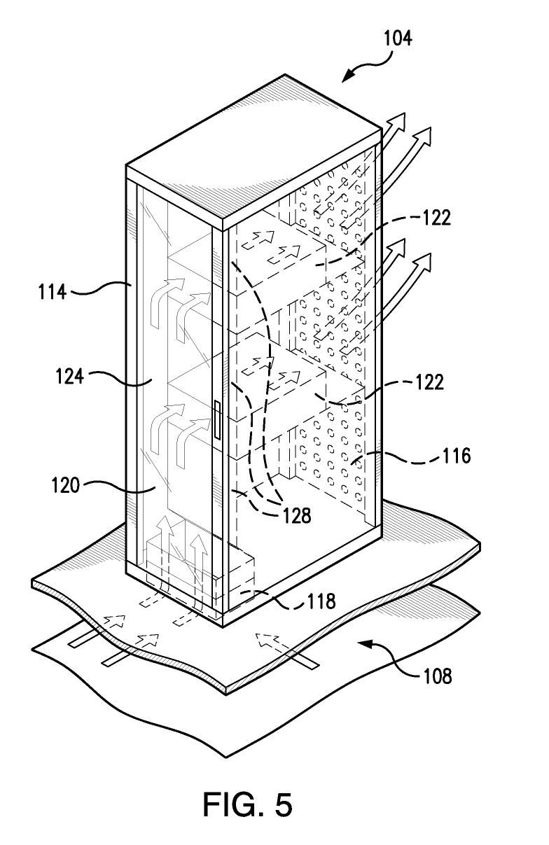

FIG. 5 illustrates the air flow through cabinet 104. As shown, cold air from CRAC 102 flows through under-floor plenum 108, through inlet duct 118, and into vertical plenum 120. Plates 128 positioned between server equipment 122 are configured to seal vertical plenum 120 such that the cold air that is forced into the plenum can only exit the plenum by traveling through server equipment 122. As shown, front portion 114 of server cabinet 104 may included front door 124. Front door 124 may be made of glass, which allows the server equipment to be monitored while still maintaining the an airtight seal within vertical plenum 120. In one exemplary embodiment, back portion 116 of server cabinet 104 comprises a panel having a plurality of perforations allowing the air that is heated as it passes through server equipment 122 to exit the server cabinet and eventually be re-circulated through CRAC 102.

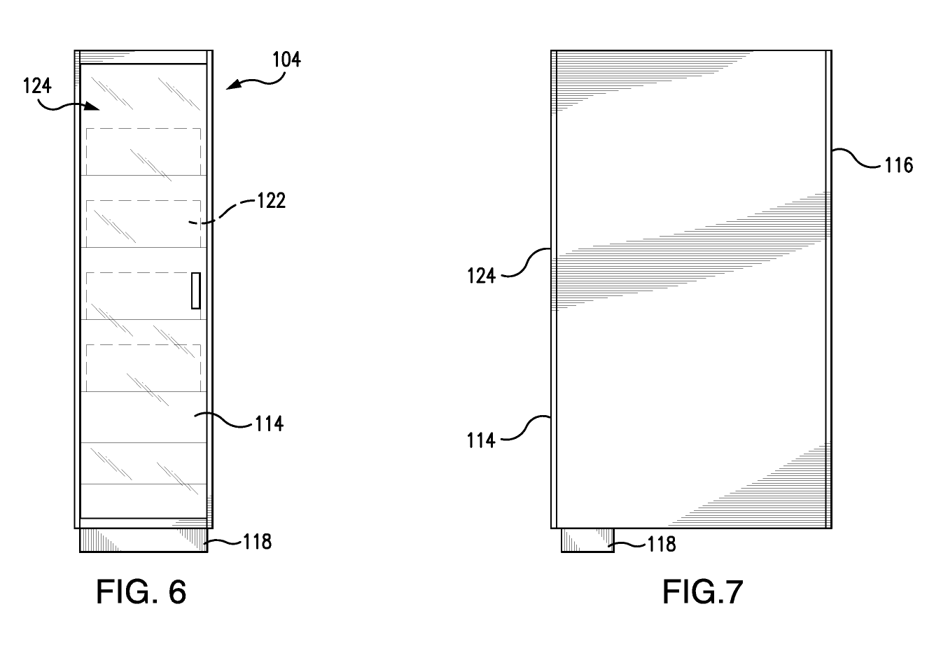

FIGS. 6-9 illustrate various orthogonal views of an exemplary embodiment of server cabinet 104. FIG. 6 shows a front view of server cabinet 104 including front door 124, which may provide access to the front portion of server equipment 122. As shown in FIG. 6, front door 124 may be made of glass or other transparent material.

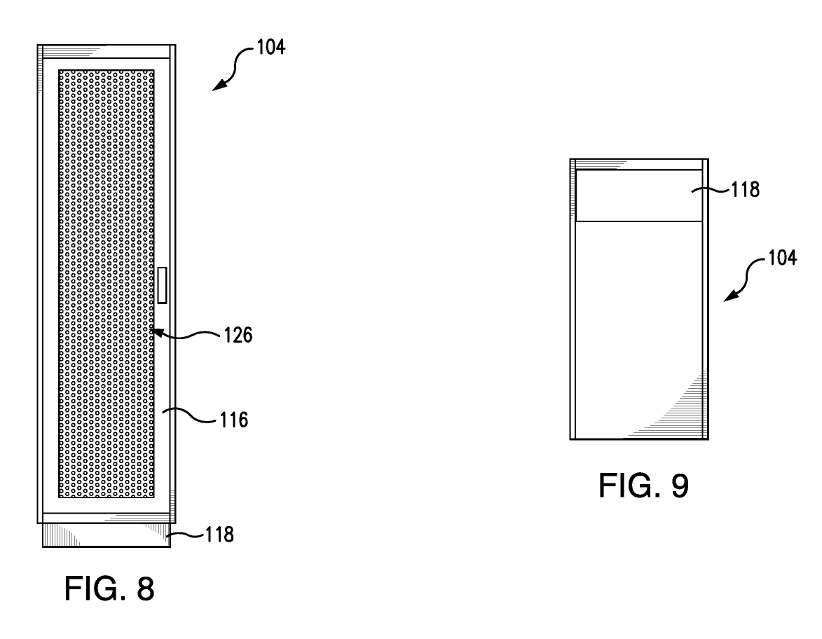

FIG. 7 shows a side view of server cabinet 104, including inlet duct 118, which is configured to fluidly connect under-floor plenum 108 with vertical plenum 120 of cabinet 104. FIG. 8 shows a rear view of server cabinet 104 including back door 126. As shown in FIG. 7, back door 126 may include a corrugated and perforated door panel that provides security for server cabinet 104 while also facilitating hot air flow from the back portions of server equipment 122 housed within server cabinet 104. FIG. 9 illustrates a bottom view of server cabinet 104, showing an additional view of inlet duct 118.

The present invention, as described above and shown in the drawings, provides for systems and methods for efficient and failsafe cooling of a server cabinet within a data center. It will be apparent to those skilled in the art that various modifications can be made to the systems and methods of the present invention without departing from the scope of the invention as outlined in the appended claims and their equivalents.

The invention claimed is:

1. A system for cooling electronic equipment in a data center, comprising:
a raised floor defining an under-floor plenum;
an air conditioner having a hot-air inlet and a cold-air outlet, wherein the cold-air outlet is in fluid communication with the under-floor plenum; and
a cabinet housing electronic equipment and including an airtight, pressurized vertical plenum in fluid communication with the under-floor plenum via an inlet duct;
wherein the cabinet is configured to receive a cold air flow from the under-floor plenum via the inlet duct into the vertical plenum and to draw the cold air across the electronic equipment to cool the electronic equipment.

2. The system of claim 1, further comprising an inflatable airfoil damper assembly disposed within the inlet duct and configured to provide failsafe variable airflow to the vertical plenum within the cabinet.

3. The system of claim 2, further comprising at least one temperature controller interfacing with the inflatable airfoil damper assembly.

4. The system of claim 3, further comprising at least one temperature sensor interfacing with the temperature controller.

5. The system of claim 4, further comprising an air compressor in communication with the controller and the airfoil damper assembly, wherein the compressor is configured to provide compressed air to inflate a plurality of airfoils within the airfoil damper assembly and to restrict the cold air flow from the under-floor plenum to the vertical plenum.

6. The system of claim 2, wherein the inflatable airfoil damper includes a plurality of inflatable airfoils.

7. The system of claim 6, wherein each of the plurality of airfoils is elongated with a longitudinal axis that is oriented in a direction that is substantially parallel to the direction of the cold air flow from the under-floor plenum to the vertical plenum.

8. The system of claim 6, wherein the orientation of the plurality of inflatable airfoils is adjustable to further control the flow of cold air from the under-floor plenum to the vertical plenum.

9. The system of claim 6, wherein each of the plurality of inflatable airfoils includes an internal air bladder in fluid communication with an air compressor via at least one pneumatic line.

10. The system of claim 1, wherein the air conditioner includes a variable air volume control configured to modulate the speed of one or more fans within the air conditioner.

11. The system of claim 1, wherein the cabinet further comprises a plurality of plates sealingly secured between the electronic equipment.

12. The system of claim 1, wherein a portion of the airtight vertical plenum is formed by a glass door of the cabinet.

13. The system of claim 1, wherein the cabinet includes a perforated panel on a rear portion of the cabinet, the perforated panel being configured to allow for the egress of heated air from the cabinet.

14. A system for cooling electronic equipment in a data center, comprising:
a raised floor defining an under-floor plenum;
an air conditioner having a hot-air inlet and a cold-air outlet, wherein the cold-air outlet is in fluid communication with the under-floor plenum;
a cabinet housing electronic equipment and including an airtight, pressurized vertical plenum in fluid communication with the under-floor plenum via an inlet duct; and
an inflatable airfoil damper assembly disposed within the inlet duct and configured to provide failsafe variable cold airflow to the vertical plenum within the server cabinet.
wherein the cabinet is configured to receive the cold airflow from the inlet duct into the vertical plenum and to draw the cold air across the electronic equipment to cool the electronic equipment.

15. A method for cooling electronic equipment in a data center comprising the steps of:
providing an air conditioner having a cold air outlet in fluid communication with an under-floor plenum;
providing a cabinet housing electronic equipment and including an airtight, pressurized vertical plenum in fluid communication with the under-floor plenum via an inlet duct;
drawing cold air produced by the air conditioner from the under-floor plenum, through the inlet duct and into the vertical plenum; and
drawing the cold air from the vertical plenum through the electronic equipment to cool the electronic equipment and to heat the air.

16. The method of claim 15, further comprising modulating the flow of cold air from the air conditioner using a variable air volume control to maintain a first set-point temperature within the under-floor plenum.

17. The method of claim 15, further comprising varying the flow of cold air through the inlet duct using an inflatable airfoil damper.

18. The method of claim 17, further comprising using the inflatable airfoil damper to maintain a set-point temperature at a back portion of the cabinet by varying the cold air that flows into the vertical plenum and through the electronic equipment.

19. The method of claim 17, wherein the step of varying the flow of cold air through the inlet duct using an inflatable airfoil damper includes inflating a plurality of elongated airfoils each having a longitudinal axis that is substantially parallel to the direction of the air flow.
